(19) United States
(12) Patent Application Publication
(10) Pub. No.: US 2015/0244385 A1
(43) Pub. Date: Aug. 27, 2015

(54) CIRCUIT INTERFACING SINGLE-ENDED INPUT TO AN ANALOG TO DIGITAL CONVERTER

(71) Applicant: QUALCOMM Incorporated, San Diego, CA (US)

(72) Inventors: Dinesh Jagannath Alladi, San Diego, CA (US); Omar Hafiz, San Diego, CA (US); Elias Hani Dagher, Aliso Viejo, CA (US)

(21) Appl. No.: 14/549,445

(22) Filed: Nov. 20, 2014

Related U.S. Application Data
(60) Provisional application No. 61/945,605, filed on Feb. 27, 2014.

(51) Int. Cl. H03M 1/06; H03M 1/18; H03M 1/12

(52) U.S. Cl. CPC H03M 1/0629; H03M 1/1245; H03M 1/186

(57) ABSTRACT

In embodiments, a circuit includes a single-ended input coupled to a first input of a differential filter. The differential filter is coupled to an analog to digital converter (ADC), and the single-ended input includes an input DC bias voltage level and an input signal. A reference generator circuit is coupled to a second input of the differential filter. The reference generator circuit generates a reference bias voltage. The differential filter includes a first filter coupled to the singled ended input and to the ADC and a second filter coupled to the reference generator circuit and to the ADC. The first filter is configured to receive the input DC bias voltage level and input signal. The second filter is configured to receive the reference bias voltage.

### CROSS REFERENCE TO RELATED APPLICATIONS

Pursuant to 35 U.S.C. § 119(e), this application is entitled to and claims the benefit of the filing date of U.S. Provisional App. No. 61/945,605 filed Feb. 27, 2014, the content of which is incorporated herein by reference in its entirety for all purposes.

### BACKGROUND

Unless otherwise indicated, the foregoing is not admitted to be prior art to the claims recited herein and should not be construed as such.

Analog-to-digital converters (ADCs) convert an analog signal into a digital signal. FIG. 1 depicts an example of a front end circuit of an analog-to-digital converter 100. The first stage of a sigma delta ADC is shown in this example. ADC 100 receives an input signal from a driver circuit 102, and includes an ADC sample-and-hold network 104 and an integrator 106. ADC sample-and-hold network 104 may be a differential switched capacitor sampler that includes capacitors Cₛ.

In operation, during a first phase Φ1, the differential input signals Vin+ and Vin− from driver circuit 102 are sampled on capacitors Cₛ. In this case, switches Φ1 are closed to couple capacitors Cₛ to driver circuit 102 and switches Φ2 are open, and the charge on capacitors Cₛ tracks the input signal. During a second phase Φ2, the switches Φ2 are closed and the switches D1 are open. The input signal charge stored on sampling capacitors Cₛ at the end of the first phase Φ1 is processed by integrator 106 to perform the conversion.

The operation of ADC sample-and-hold network 104 is inherently high-speed, such as at a clock frequency Fs. The input signal charge is delivered to capacitors Cₛ within phase Φ1. Driver circuit 102 also should be able to charge capacitors Cₛ and achieve a good settling of the value within phase Φ1. Meeting the settling requirements is critical to achieve good linearity in the ADC. This requires a wide bandwidth driver (e.g., bandwidth >>Fs) with a high slew rate. Using a wide bandwidth driver makes power, noise, and supply rejection of the driver a concern. Also, due to using a differential input, the wide bandwidth is required for both Vin+ and Vin−.

ADC sample-and-hold network 104 may operate at high frequencies, such as around the sampling clock frequency Fs compared to the input signal frequency. An anti-aliasing filter (AAF) may be employed to filter unwanted high-frequency input to prevent aliasing of high frequency noise and unwanted signals (e.g., jammers) outside the bandwidth of interest. However, when a single-ended signal is used, problems may result. FIG. 2 depicts an example of an ADC 200 using a single-ended input. A single-ended input is received at 202. An active or passive anti-aliasing filter (AAF) 204 receives the single-ended input. AAF 204 inputs the single-ended input signal into a positive side of sample-and-hold network 104. As discussed above, the input signal charges capacitors Cₛ.

The single-ended input may include an average offset or input DC (direct current) bias voltage level and a varying or alternating current (AC) input signal. A reference signal also needs to be generated for input into the negative side of ADC sample-and-hold network 208. To minimize dynamic range requirements of the ADC, this reference should be nominally close to the DC level of the input signal. A reference buffer 206 receives a low noise reference and can output the reference signal. The output of reference buffer 206 is then input into the negative side of ADC sample-and-hold network 208 to cancel the DC bias voltage level of the single-ended input. The ADC can then process the input signal with the DC bias voltage level canceled.

The above design results in low noise and high slew rate/settling requirements for reference buffer 206, which may use a large amount of power in implementation. Also, a circuit for AAF 204 uses a large amount of area on the chip.

### SUMMARY

In embodiments, a circuit includes a single-ended input coupled to a first input of a differential filter. The differential filter is coupled to an analog to digital converter (ADC), and the single-ended input includes an input DC bias voltage level and an input signal. A reference generator circuit is coupled to a second input of the differential filter. The reference generator circuit generates a reference bias voltage. The differential filter includes a first filter coupled to the singled ended input and to the ADC and a second filter coupled to the reference generator circuit and to the ADC. The first filter is configured to receive the input DC bias voltage level and input signal. The second filter is configured to receive the reference bias voltage.

In one embodiment, the reference generator circuit comprises a low noise reference generator configured to generate the reference bias voltage.

In one embodiment, the reference generator circuit comprises a reference buffer configured to buffer the reference bias voltage.

In one embodiment, the reference generator circuit comprises a third filter configured to couple ground noise to an input of the reference buffer, and the coupled ground noise tracks ground noise coupled to the single-ended input.

In one embodiment, the circuit further includes a differential capacitor network coupled differentially to the first filter and the second filter.

In one embodiment, the differential filter comprises a differential anti-aliasing filter.

In one embodiment, the differential filter is coupled to a sample and hold switched capacitor network of the ADC.

In one embodiment, a system includes: a single-ended input coupled to a first input of a differential filter, wherein the differential filter is coupled to an analog to digital converter (ADC), and wherein the single-ended input comprises a input DC bias voltage level and an input signal; a reference generator circuit configured to generate a reference bias voltage; and a reference buffer coupled to the reference generator circuit to receive the reference bias voltage, and coupled to a second input of the differential filter to provide the reference bias voltage to the second input, wherein the differential filter comprises: a first filter coupled to the singled ended input and to the ADC, the first filter configured to receive the input DC bias voltage level voltage and input signal; and a second filter coupled to the reference buffer and to the ADC, the second filter configured to receive the reference bias voltage.

The following detailed description and accompanying drawings provide a better understanding of the nature and advantages of the present disclosure.

### BRIEF DESCRIPTION OF THE DRAWINGS

With respect to the discussion to follow and in particular to the drawings, it is stressed that the particulars shown represent examples for purposes of illustrative discussion, and are presented in the cause of providing a description of principles and conceptual aspects of the present disclosure. In this regard, no attempt is made to show implementation details beyond what is needed for a fundamental understanding of the present disclosure. The discussion to follow, in conjunction with the drawings, make apparent to those of skill in the art how embodiments in accordance with the present disclosure may be practiced. In the accompanying drawings:

FIG. 1 depicts an example of an analog-to-digital converter (ADC).

FIG. 2 depicts an example of an ADC using a single-ended input.

FIG. 3 depicts a circuit for providing an interface for a single-ended input to an ADC according to one embodiment.

FIG. 4 depicts a more detailed example of the circuit according to one embodiment.

FIG. 5 depicts an example of a circuit using a differential capacitor network according to one embodiment.

FIG. 6A shows an example of two single-ended anti-aliasing filters (AAFs) according to one embodiment.

FIG. 6B shows an example of a fully-differential AAF according to one embodiment.

FIG. 7 depicts a simplified flowchart for operating a sample-and-hold network according to one embodiment.

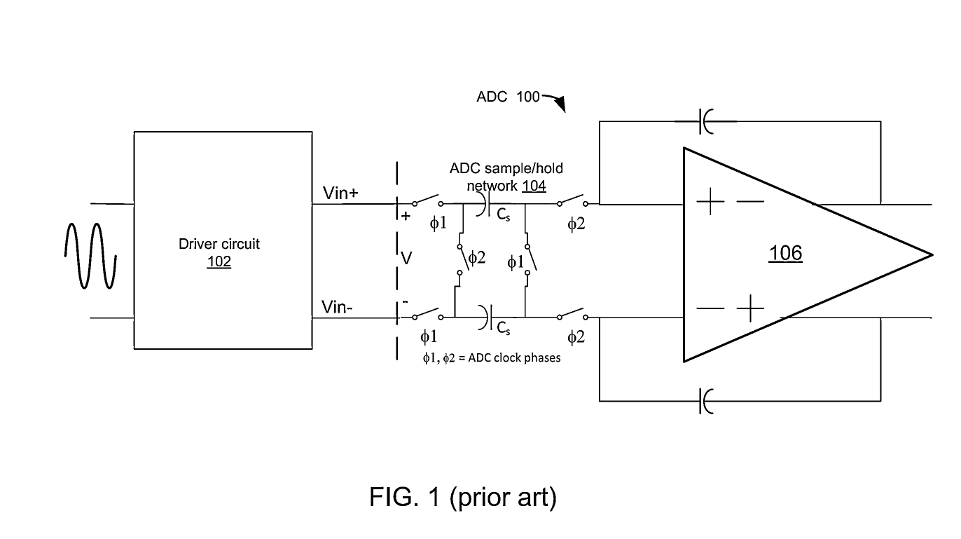

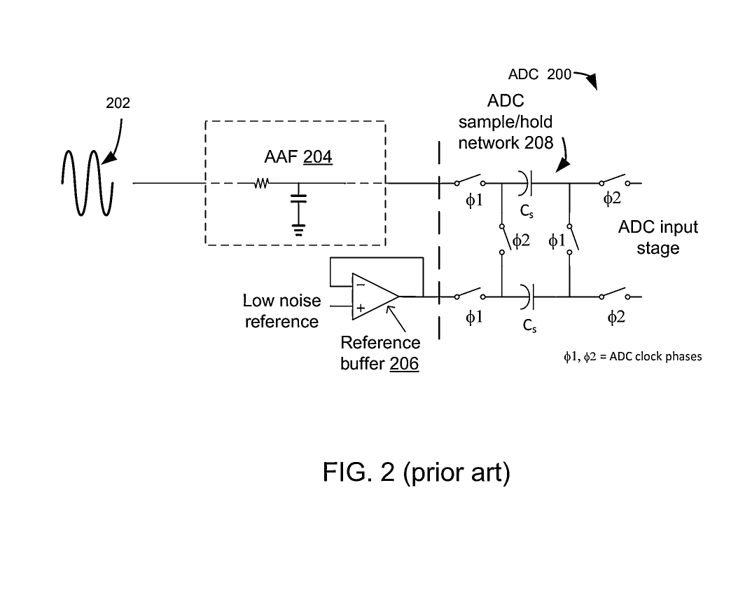

### DETAILED DESCRIPTION

Disclosed embodiments relate to an interface for an analog-to-digital converter (ADC). In the following description, for purposes of explanation, numerous examples and specific details are set forth in order to provide a thorough understanding of the present disclosure. It will be evident, however, to one skilled in the art that the present disclosure as expressed in the claims may include some or all of the features in these examples, alone or in combination with other features described below, and may further include modifications and equivalents of the features and concepts described herein.

A single-ended input reduces the number of pins required for analog-to-digital converter (ADC) inputs in certain systems thereby reducing system costs (e.g., package and board routing costs). Particular embodiments provide a reference buffer and a differential filter (e.g., an anti-alias filter (AAF)) architecture that interfaces a single-ended input to an ADC. For example, the AAF interfaces with a switched capacitor sample and hold network of the ADC. The AAF is needed for anti-aliasing in the signal path and also to filter unwanted jammers outside the signal bandwidth of interest. For a single-ended input, an internal (e.g., on-chip) reference DC bias voltage is also needed. In one embodiment, the reference DC bias voltage may be substantially the same as a DC bias voltage level of the single-ended input signal to reduce offset of the single-ended input and reduce ADC dynamic range requirements when the single-ended input is used. Particular embodiments use the reference buffer to drive the AAF in a differential fashion in contrast to driving the switched capacitor ADC sample and hold network directly with the reference buffer. This allows for the use of a low bandwidth buffer and reduces power, noise, slew rate, and power supply rejection ratio (PSRR) requirements of the reference buffer.

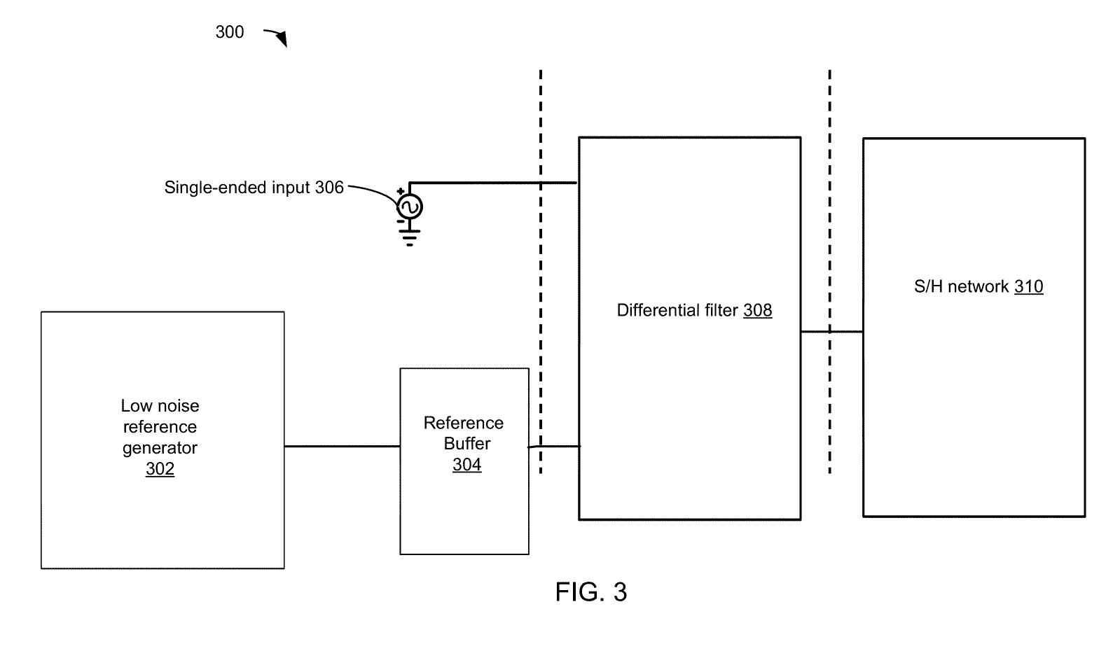

FIG. 3 depicts a circuit 300 for providing an interface for a single-ended input to an ADC according to one embodiment. Circuit 300 includes a reference generator 302, a reference buffer 304, a single-ended input 306, a differential filter 308, and a sample-and-hold (S/H) network 310. Reference generator 302, reference buffer 304, differential filter 308, and sample-and-hold network 310 are located on-chip. Single-ended input 306 is generated off-chip.

Sample-and-hold network 310 may interface with an ADC front-end (not shown) of the ADC (not shown). In one embodiment, sample-and-hold network 310 may be a switched capacitor design. However, differential filter 308 may interface with other implementations of front-ends of ADCs.

Single-ended input 306 may be an external single-ended input that may include an input DC bias voltage level and an input voltage signal that may be time varying (e.g., an alternating current (AC) signal). As discussed above, when a single-ended input is used, a reference bias level is needed to reduce the offset of the single-ended input and reduce ADC dynamic range requirements.

Reference generator 302 may generate a reference bias voltage signal that can be used to cancel the input DC bias voltage level of the single-ended input. In one embodiment, reference generator 302 generates a low noise reference signal. The low noise may reduce the noise introduced into the ADC. Reference buffer 304 receives the reference bias signal from reference generator 302 and outputs a reference bias voltage into differential filter 308. The reference bias voltage may substantially equal the input DC bias voltage level.

Differential filter 308 may be differential in that filter 308 includes a positive side and a negative side. In one embodiment, a first filter may be provided for the positive side and a second filter is provided for the negative side. That is, the first filter for the positive side is coupled to single-ended input 306 and the second filter for the negative side is coupled to reference buffer 304. As will be discussed in more detail below, differential filter 308 may be a passive anti-aliasing (AAF) filter that includes one or more resistor capacitor (RC) filters.

Using differential filter 308 may provide many advantages. For example, differential filter 308 may relax the bandwidth of reference buffer 304 to be comparable to signal bandwidths determined by differential filter 308. Also, differential filter 308 may filter high frequency noise and PSRR from the single-ended input signal and the reference signal. Further, using differential filter 308, the linearity requirements on reference buffer 304 are relaxed due to the resistance provided in the resistor capacitor filters. These advantages will be discussed in more detail below.

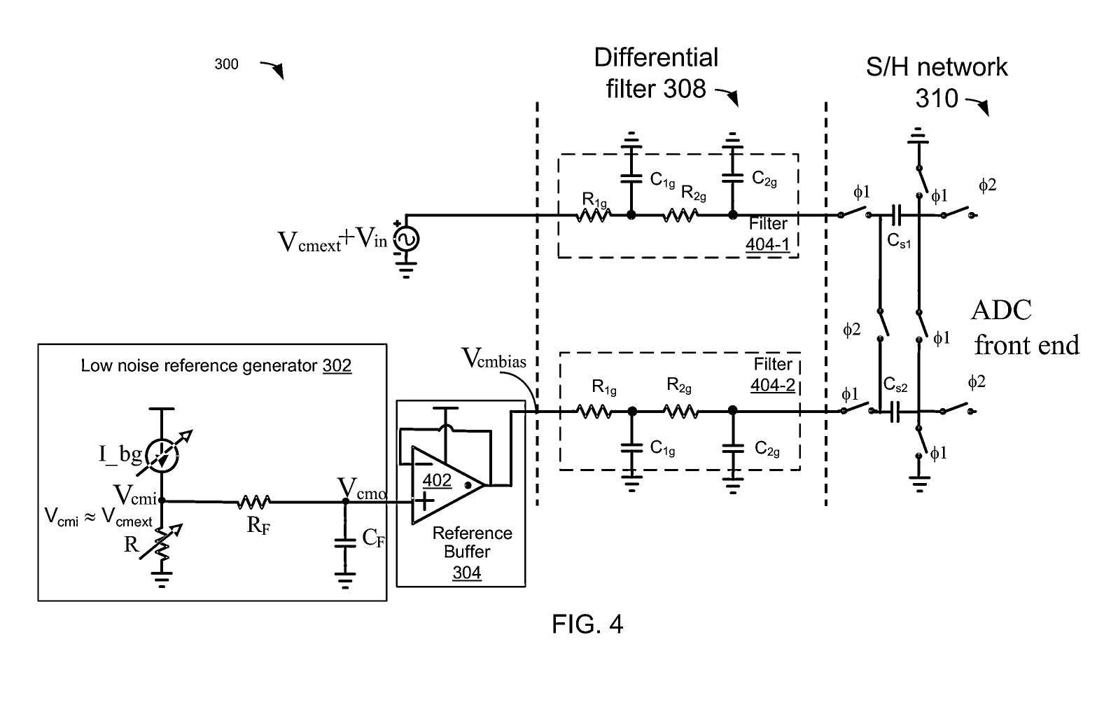

FIG. 4 depicts a more detailed example of circuit 300 according to one embodiment. Single-ended input 306 is received externally and may include an input DC bias voltage level Vcmext and input signal Vin. DC level Vcmext may be an external offset of the single-ended alternating current (AC) signal Vin. The single-ended input is input into a first input of differential filter 308.

As discussed above, when a single-ended input is used, a reference bias voltage is needed to reduce the offset of the single-ended input and ADC dynamic range requirements. Reference generator 302 may generate a low noise reference signal Vcmo that is input into reference buffer 304. Although this low-noise reference generator is described, other architectures may be used. In one embodiment of reference generator 302, a band gap current I_bg is used to generate a reference bias voltage Vcmi that substantially matches the input DC voltage level Vcmext of the single-ended input. The voltage Vcmi is generated using a current source I_bg and a resistor R, but other implementations may be used. As discussed above, the voltage Vcmi is an internally generated (e.g., on-chip) reference signal.

In one embodiment, reference generator 302 includes a resistor capacitor (RC) filter R_{F}C_{F} that is used to filter the band gap noise. Also, filter R_{F},C_{F} couples ground noise to the reference buffer input. The single-ended input typically has an implicit reference (e.g., ground). A large C_{F} filters more noise from the bandgap current and couples high frequency ground noise to reference buffer 304, while resistor R_{F} couples low frequency ground noise below the cutoff frequency of filter R_{F}C_{F}. Coupling the ground noise to reference generator 302 allows reference generator 302 and reference buffer 304 to track ground noise up to the signal bandwidth resulting in good ground noise immunity. That is, both the single-ended input signal and the reference signal are coupled to ground and thus any ground noise that is seen by the single-ended input is also seen by the reference signal. That is, the ground noise is tracked by the reference signal to match the ground noise of the single-ended input. In this embodiment, reference bias voltage Vcmo substantially matches the input DC voltage level Vcmext of the single-ended input with ground noise tracking.

Reference generator 302 then provides the voltage signal Vcmo to reference buffer 304. Reference buffer 304 may include a buffer 402 that receives the reference signal Vcmo. Buffer 402 may buffer/amplify the reference signal Vcmo, and output the reference signal Vcmbias to differential filter 308. The voltage Vcmbias may be used to cancel the input DC bias voltage level of the single-ended input.

In one embodiment, reference buffer 304 may be a class AB buffer. However, although a class AB buffer is described, reference buffer 304 may be a different type of buffer. In one embodiment, a class AB buffer may be used with a DC impedance smaller than the resistor R_{1g} of differential filter 308. Reference buffer 304 is a class AB buffer with a push-pull source follower stage. The class AB buffer provides low output impedance. Also, reference buffer 304 tracks ground noise up to the signal bandwidth also.

Differential filter 308 may include a first filter 404-1 and a second filter 404-2. First filter 404-1 may be coupled to a positive side of differential filter 308 and second filter 404-2 may be coupled to a negative side of differential filter 308.

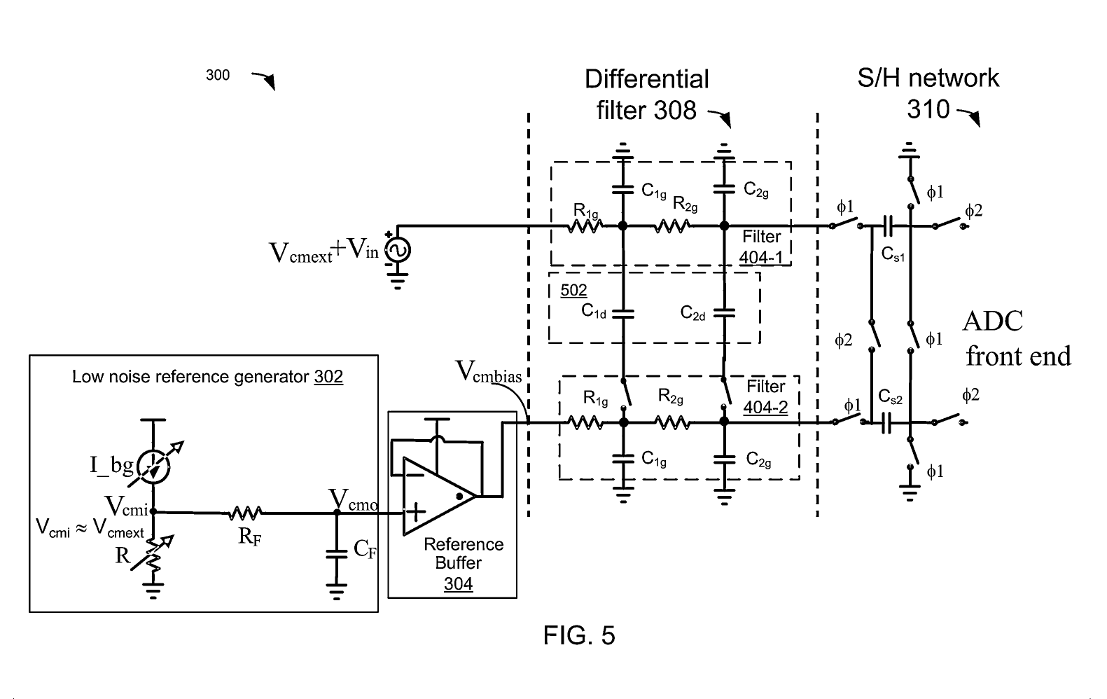

In one embodiment, filters 404 may be passive filters, such as passive AAF filters, but other filters, such as active filters, may be used. The anti-aliasing filter is a filter that restricts the bandwidth of the single-ended input signal and the reference signal to approximately satisfy the sampling requirements of the ADC. For example, the AAF filters noise and PSRR of the reference buffer and the input signal. A two pole filter is shown, but a filter with any number of poles may be used. The positive side of differential filter 308 includes RC pairs of resistor R_{1g}, capacitor C_{1g}, and resistor R_{2g}, capacitor C_{2g}. The negative side of differential filter 308 includes also includes the same RC pairs resistor R_{1g}, capacitor C_{1g}, and resistor R_{2g} and capacitor C_{2g}. Although the positive and negative side include RC pairs of resistor R_{1g}, capacitor C_{1g}, and resistor R_{2g}, capacitor C_{2g}, that are labeled with the same identifier, the values of the resistors and capacitors may be different on the positive and negative sides. For example, resistor R_{1g}, capacitor C_{1g}, and resistor R_{2g}, capacitor C_{2g} could be different on in filter 404-2 from resistor R_{1g}, capacitor C_{1g}, and resistor R_{2g}, capacitor C_{2g} in filter 404-1. Further the negative side may also have a different number of RC poles. One benefit of having them the same is better linearity from sampling switches, flat inband frequency response from the filters, and the optional area benefit from the differential capacitors C1d, C2d described later (shown in FIG. 5). However, different values for R1g, R2g, C1g, C2g for filter 404-2 may lower bandwidth for the reference generator, such as using large capacitors may relax the buffer bandwidth requirements further, and filter reference buffer noise more.

The single-ended input is coupled to a first side (e.g., positive side) of differential filter 308 and reference buffer 304 is coupled to a second side (e.g., negative side) of differential filter 308.

Using second filter 404-2 as an example, the reference signal Vcmbias may include high frequency and low frequency components. Second filter 404-2 may attenuate the high frequency input signals from the reference signal Vcmbias. The low frequency signal is provided to sample-and-hold network 310 by buffer 402. Then, at high frequencies, the capacitors C_{1g} and C_{2g} provide current to sample-and-hold network 310. For example, there is good settling between capacitors C_{1g} and C_{2g} and sampling capacitors Cₛ₁ and Cₛ₂ of sample-and-hold network 310. That is, buffer 402 does not need to provide a charge at high frequencies. This reduces the requirement on buffer 402 at high frequencies. That is, the bandwidth of an op amp in buffer 402 does not need to be large because it only needs to provide low frequency current, and not high frequency current. The low bandwidth requirements of reference buffer 304 enable a low noise buffer design.

Also, at low frequencies, the linearity requirements of reference buffer 304 are reduced because the reference buffer's DC output impedance is in series with resistor R_{1g}, which may be relatively large and linear in comparison to the output impedance of reference buffer 304. That is, a small non-linearity in the output impedance of reference buffer 304 is minimized due to the size of resistor R_{1g}, which relaxes the linearity requirements for reference buffer 304. For example, if the resistor R_{1g} is large compared to the output resistance of reference buffer 304, then the output resistance of reference buffer 304 may be non-linear because its effect on the overall resistance seen by sample-and-hold network 310 is minimal For example, if the resistance of resistor R_{1g} is 1k ohm, and the output resistance of reference buffer 304 is 1 ohm, then any variations in the 1 ohm output resistance has very little effect on the resistance of resistor R_{1g}. Also, as the frequency increases, capacitor C_{1g} dominates the output impedance and any peaking in the output impedance of reference buffer 302 has little effect on the reference signal Vcmbias.

Also, capacitors C_{1g} and C_{2g} help filter jammer and reduce the requirements on the reference buffer to provide current at high frequencies. To reduce jammer or other noise, the capacitors filter high-frequency signals in both directions. For example, resistor R_{1g} and capacitor C_{1g} (and resistor R_{2g} and capacitor C_{2g}) filter high-frequency current signals and noise from reference buffer 302 going into the ADC. In the other direction, capacitor C_{2g} and resistor R_{2g} (and capacitor C_{1g} and resistor R_{1g}) filter high-frequency current signals from the ADC to reference buffer 302.

Other advantages particular embodiments provide are relaxed bandwidth and slew requirements on reference buffer 302. These requirements may be small compared to the ADC clock frequency, and are only determined by the resistor capacitor (RC) corner of filters 404. In comparison, buffer 206 would need much wider bandwidth than the clock frequency Fs. Also, particular embodiments provide good ground noise immunity because the low-reference noise generator 302 and reference buffer 304 track ground noise up to the input signal bandwidth.

Further, circuit 100 may save area by using differential capacitors in differential filter 308. Differential capacitors may provide an area reduction benefit if linearity is acceptable. For example, a differential capacitor network may be used in differential filter 308. FIG. 5 depicts an example of circuit 300 using a differential capacitor network 502 according to one embodiment. As shown, differential capacitor network 502 includes a first capacitor C_{1d} and a second capacitor C2d, but additional capacitors may be used. Capacitors C_{1d} and C2d are differential capacitors in that they are coupled between first filter 404-1 and second filter 404-2. In this case, differential capacitors C_{1d} and C_{2d} are not directly coupled to ground like capacitors C_{1g} and C_{2g}.

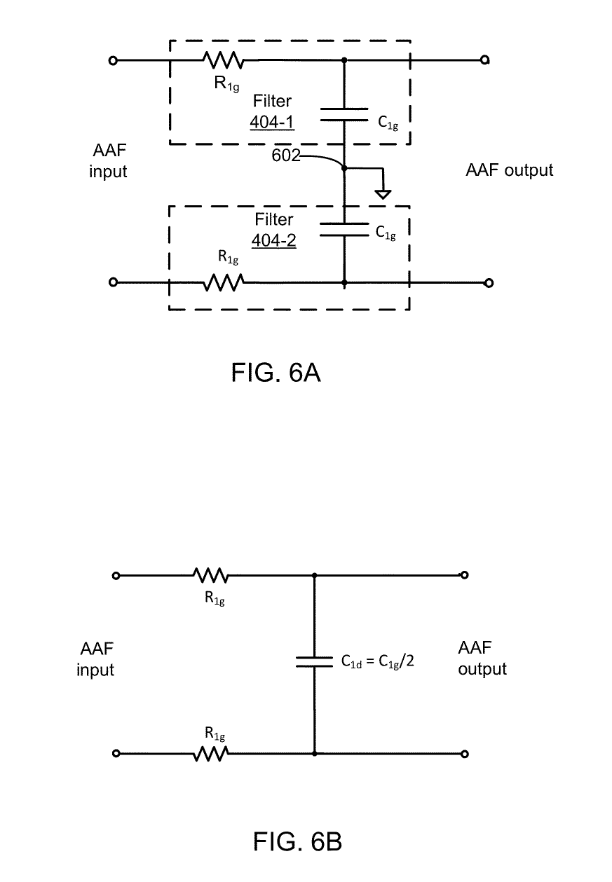

In one embodiment, differential capacitor network 502 may be used to replace some capacitance provided by capacitors C_{1g} and C_{2g}. For example, the capacitance values of C_{1g} and C_{2g} may be reduced. The reduced capacitance is then replaced by capacitance provided by differential capacitor network 502. One reason why differential capacitor network 502 may be used is that a differential AAF may be implemented as two single-ended AAFs. FIG. 6A shows an example of two single-ended AAFs according to one embodiment. As shown, first filter 404-1 includes a resistor R_{1g} and a capacitor C_{1g} and filter 404-2 includes a resistor R_{1g} and a capacitor C_{1g}. Filter 404-1 and filter 404-2 are both coupled to a middle-grounded node at 602. For a differential input, the middle-grounded node does not carry any current. Hence, the two capacitors C_{1g} are effectively in series. This means the effective capacitance is C_{1g}/2.

FIG. 6B shows an example of a fully-differential AAF according to one embodiment. In this case, capacitors C_{1g} and C_{2g} have been replaced with capacitor C_{1d}, which is equal to C_{1g}/2. By using the differential capacitor network 502, total capacitance area may be ¼ the single-ended capacitance because two capacitors C_{1g} are replaced by one capacitor C_{1g}, which equals half of the capacitance of C_{1g} (e.g., C_{1g}/2).

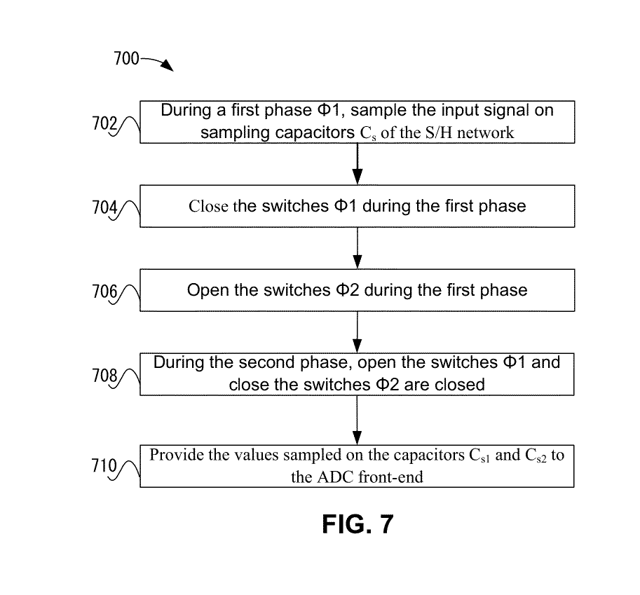

FIG. 7 depicts a simplified flowchart 700 for operating sample-and-hold network 310 according to one embodiment. At 702, for the sample and hold network 310, during a first phase Φ1, the input signal is sampled on sampling capacitors Cₛ of the S/H network. At 704, in this case, the switches Φ1 are closed. Also, at 706, the switches Φ2 are open during the first phase. During the first phase, a filtered version of the single-ended input signal Vcmi+Vin is sampled on capacitor Cₛ₁ and a filtered version of the signal Vcmbias is sampled on capacitor Cₛ₂. As discussed above, the signal Vcmbias is coupled through the negative side of differential filter 308 to capacitor Cₛ₂. This provides the advantages as described above.

At 708, during the second phase, the switches Φ1 are open and the switches Φ2 are closed. At 710, the values sampled on the capacitors Cₛ₁ and Cₛ₂ are provided to the ADC front-end. The reference bias voltage may be substantially the same as the DC value of the single-ended input signal and is used to offset the input DC bias voltage level of the single-ended input. The signal Vin is thus provided to the ADC.

The above description illustrates various embodiments of the present disclosure along with examples of how aspects of the particular embodiments may be implemented. The above examples should not be deemed to be the only embodiments, and are presented to illustrate the flexibility and advantages of the particular embodiments as defined by the following claims. Based on the above disclosure and the following claims, other arrangements, embodiments, implementations and equivalents may be employed without departing from the scope of the present disclosure as defined by the claims.

We claim the following:

1. A circuit comprising:
a single-ended input coupled to a first input of a differential filter, wherein the differential filter is coupled to an analog to digital converter (ADC), and wherein the single-ended input comprises an input DC bias voltage level and an input signal; and
a reference generator circuit coupled to a second input of the differential filter, the reference generator circuit generating a reference bias voltage,
wherein the differential filter comprises:
a first filter coupled to the singled ended input and to the ADC, the first filter configured to receive the input DC bias voltage level and input signal; and
a second filter coupled to the reference generator circuit and to the ADC, the second filter configured to receive the reference bias voltage.

2. The circuit of claim 1, wherein the reference generator circuit comprises a low noise reference generator configured to generate the reference bias voltage.

3. The circuit of claim 2, wherein the reference generator circuit comprises a reference buffer configured to buffer the reference bias voltage.

4. The circuit of claim 3, wherein the reference generator circuit comprises a third filter configured to couple ground noise to an input of the reference buffer, and wherein the coupled ground noise tracks ground noise coupled to the single-ended input.

5. The circuit of claim 3, wherein the output of the reference buffer is coupled to the second input of the differential filter to provide the reference bias voltage to the second filter.

6. The circuit of claim 2, wherein the reference generator circuit comprises a third filter configured to filter noise from the reference bias voltage.

7. The circuit of claim 1, wherein:
the first filter comprises one or more first resistor capacitor filters, and
the second filter comprises one or more second resistor capacitor filters.

8. The circuit of claim 7, wherein the one or more first resistor capacitor filters and the one or more second resistor capacitor filters filter noise at high frequencies.

9. The circuit of claim 7, wherein the one or more second resistor capacitor filters comprise a resistor in series with a reference buffer of the reference generator circuit, wherein a resistance of the resistor is larger than an output resistance of the reference buffer.

10. The circuit of claim 1, further comprising:
a differential capacitor network coupled differentially to the first filter and the second filter.

11. The circuit of claim 10, wherein:
the first filter comprises a first resistor coupled to the differential capacitor network, and
the second filter comprises a second resistor coupled to the differential capacitor network.

12. The circuit of claim 1, wherein the differential filter comprises a differential anti-aliasing filter.

13. The circuit of claim 1, wherein the differential filter is coupled to a sample and hold switched capacitor network of the ADC.

14. A system comprising:
a single-ended input coupled to a first input of a differential filter, wherein the differential filter is coupled to an analog to digital converter (ADC), and wherein the single-ended input comprises an input DC bias voltage level and an input signal;
a reference generator circuit configured to generate a reference bias voltage; and
a reference buffer coupled to the reference generator circuit to receive the reference bias voltage, and coupled to a second input of the differential filter to provide the reference bias voltage to the second input,
wherein the differential filter comprises:
a first filter coupled to the singled ended input and to the ADC, the first filter configured to receive the input DC bias voltage level and input signal; and
a second filter coupled to the reference buffer and to the ADC, the second filter configured to receive the reference bias voltage.

15. The system of claim 14, wherein the reference generator circuit comprises a third filter configured to couple ground noise to an input of the reference buffer, and wherein the coupled ground noise tracks ground noise coupled to the single-ended input.

16. The system of claim 14, wherein the reference generator circuit comprises a third filter configured to filter noise from the reference bias voltage.

17. The system of claim 14, wherein:
the first filter comprises one or more first resistor capacitor filters, and
the second filter comprises one or more second resistor capacitor filters.

18. The system of claim 14, further comprising:
a differential capacitor network coupled differentially to the first filter and the second filter.

19. The system of claim 18, wherein:
the first filter comprises a first resistor coupled to the differential capacitor network, and
the second filter comprises a second resistor coupled to the differential capacitor network.

20. The system of claim 14, wherein the differential filter is coupled to a sample and hold switched capacitor network of the ADC.
